(19) United States
(12) Patent Application Publication
(10) Pub. No.: US 2024/0206236 A1
(43) Pub. Date: Jun. 20, 2024

(54) DISPLAY DEVICE AND METHOD OF MANUFACTURING THE SAME

(71) Applicant: Samsung Display Co., LTD., Yongin-si (KR)

(72) Inventors: HYE SUN KIM, Yongin-si (KR); JUNGI KIM, Yongin-si (KR); SANGHYUN YUN, Yongin-si (KR); GWANGMIN CHA, Yongin-si (KR)

(21) Appl. No.: 18/388,832

(22) Filed: Nov. 11, 2023

(30) Foreign Application Priority Data
Dec. 15, 2022 (KR) 10-2022-0175683

(51) Int. Cl. H10K 59/122; H10K 59/12; H10K 59/80

(52) U.S. Cl. CPC H10K 59/122; H10K 59/1201; H10K 59/8792

(57) ABSTRACT

A display device includes a substrate, a via insulating layer disposed on the substrate and defining a groove, a lower electrode disposed on the via insulating layer and spaced apart from the groove in a plan view, a pixel defining layer disposed on the via insulating layer, defining an opening exposing at least a part of an upper surface of the lower electrode, and filling the groove, and a light-emitting layer disposed in the opening of the pixel defining layer.

This application claims priority to Korean Patent Application No. 10-2022-0175683, filed on Dec. 15, 2022, and all the benefits accruing therefrom under 35 USC § 119, the content of which in its entirety is herein incorporated by reference.

### BACKGROUND

### 1. Field

Embodiments provide generally to display device. More particularly, embodiments relate to a display device and a method of manufacturing the same.

### 2. Description of the Related Art

With a development of information technology, an importance of a display device, which is a connection medium between a user and information, is being highlighted. For example, a use of display devices such as liquid crystal display device (“LCD”), organic light-emitting display device (“OLED”), plasma display panel device (“PDP”), quantum dot display device or the like is increasing.

The display device may include sub-pixels implementing red, green, and blue light. A light-emitting layer and a functional layer may be formed in each of the sub-pixels. For example, the light-emitting layer may be formed using an inkjet printing method.

### SUMMARY

Embodiments provide a display device with improved spot defects.

Embodiments provide a method of manufacturing the display device.

A display device in an embodiment of the disclosure includes a substrate, a via insulating layer disposed on the substrate and defining a groove, a lower electrode disposed on the via insulating layer and spaced apart from the groove in a plan view, a pixel defining layer disposed on the via insulating layer, defining an opening exposing at least a part of an upper surface of the lower electrode, and filling the groove, and a light-emitting layer disposed in the opening of the pixel defining layer.

In an embodiment, the lower electrode may include a first part including an upper surface exposed by the opening and a second part spaced apart from the first part and surrounded by the groove in the plan view.

In an embodiment, the pixel defining layer may include a first area defining the opening and covering at least a part of the first part of the lower electrode and a second area overlapping the second part of the lower electrode in the plan view.

In an embodiment, with respect to the upper surface of the lower electrode, a height of an upper surface of the pixel defining layer in the second area may be greater than a height of the upper surface of the pixel defining layer in the first area.

In an embodiment, with respect to the upper surface of the lower electrode, a height of an upper surface of the pixel defining layer in the first area may be less than about 1.0 micrometer.

In an embodiment, a surface of the pixel defining layer may have liquid repellency.

In an embodiment, the pixel defining layer may include an inorganic material including a light blocking material with black color or an organic material including the light-blocking material with the black color

In an embodiment, an upper surface of the light-emitting layer may have a concave cross-sectional shape toward the substrate.

In an embodiment, the via insulating layer may include a positive photosensitive material.

A method for manufacturing a display device in embodiments of the disclosure includes forming a first preliminary layer on a substrate, forming a lower electrode on the first preliminary layer, forming a via insulating layer defining a groove by patterning the first preliminary layer using the lower electrode as a mask, forming a second preliminary layer on the lower electrode and the via insulating layer to cover the lower electrode and fill the groove, and forming a pixel defining layer defining an opening exposing at least a part of an upper surface of the lower electrode by patterning the second preliminary layer through a mask.

In an embodiment, the method for manufacturing the display device may further include forming a light-emitting layer in the opening of the pixel defining layer after the forming the pixel defining layer. The light-emitting layer may be formed through an inkjet printing method.

In an embodiment, an upper surface of the light-emitting layer may be formed to have a concave cross-sectional shape toward the substrate.

In an embodiment, each of the first preliminary layer and the second preliminary layer may include a positive photosensitive material.

In an embodiment, a surface of the pixel defining layer may have liquid repellency.

In an embodiment, the pixel defining layer may include an inorganic material including a light blocking material with black color or an organic material including the light blocking material with the black color.

In an embodiment, in the forming of the secondary preliminary layer, the second preliminary layer may be formed along the profile of the lower electrode and the groove.

In an embodiment, the lower electrode may include a first part including an upper surface exposed by the opening and a second part spaced apart from the first part and surrounded by the groove in a plan view. In addition, the pixel defining layer may include a first area defining the opening and covering at least a part of the first part of the lower electrode and a second area overlapping the second part of the lower electrode in the plan view.

In an embodiment, with respect to the upper surface of the lower electrode, a height of an upper surface of the pixel defining layer in the second area may be greater than a height of the upper surface of the pixel defining layer in the first area.

In an embodiment, with respect to the upper surface of the lower electrode, a height of an upper surface of the pixel defining layer in the first area may be less than about 1.0 micrometer.

In a display device according to the disclosure, as a groove is defined in a via insulating layer and a pixel defining layer fills the groove of the via insulating layer, the pixel defining layer may have different heights depending on position with respect to an upper surface of a lower electrode.

Accordingly, with respect to the upper surface of the lower electrode, a height of an upper surface of the pixel defining layer may decrease in an area adjacent to an opening of the pixel defining layer. In this case, a thickness deviation of a light-emitting layer disposed in the opening for each sub-pixel may be reduced. As a result, stain defects of the display device may be improved.

In addition, as the pixel defining layer has different heights depending on position, the pixel defining layer may serve as a spacer in an area where a height of the upper surface of the pixel defining layer with respect to the upper surface of the lower electrode is the highest.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating an embodiment of a display device.

FIG. 2 is a cross-sectional view taken along line I-I′ of FIG. 1.

FIG. 3 is a plan view illustrating a pixel arrangement of the display device of FIG. 1.

FIG. 4 is a cross-sectional view taken along line II-II′ of FIG. 3.

FIG. 5 is an enlarged cross-sectional view of area ‘A’ of FIG. 4.

FIGS. 6, 7, 8, 9, 10, 11, and 12 are cross-sectional views illustrating an embodiment of a method of manufacturing a display device.

### DETAILED DESCRIPTION

Hereinafter, a display device and a method of manufacturing the display device in embodiments of the disclosure will be explained in detail with reference to the accompanying drawings. The same reference numerals are used for the same components in the drawings, and redundant descriptions of the same components will be omitted.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

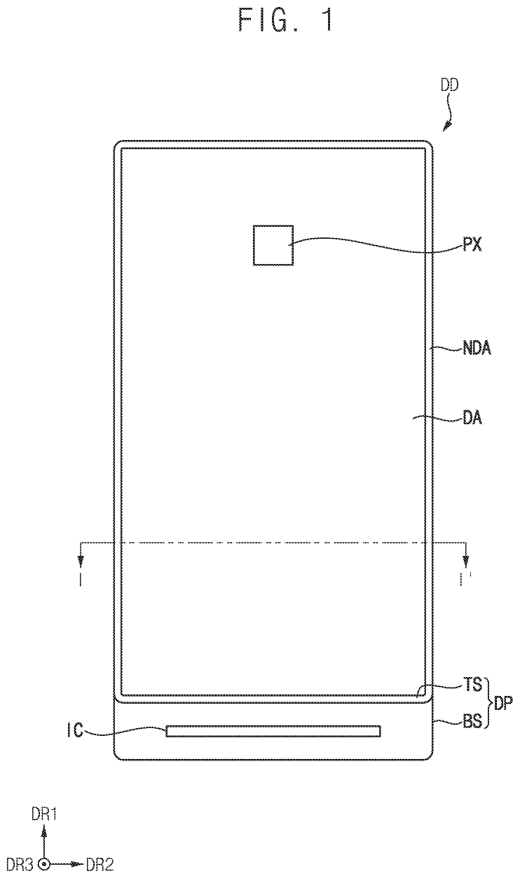

FIG. 1 is a plan view illustrating an embodiment of a display device.

In this specification, a plane may be defined as a first direction DR1 and a second direction DR2 crossing the first direction DR1. In an embodiment, the first direction DR1 and the second direction DR2 may be perpendicular to each other, for example. A direction normal to the plane, that is, a thickness direction of a display device DD may be a third direction DR3. In other words, the third direction DR3 may be perpendicular to each of the first direction DR1 and the second direction DR2.

Referring to FIG. 1, the display device DD in an embodiment of the disclosure may include a display panel DP and a driving chip IC. Here, the display panel DP may include an upper substrate TS and a lower substrate BS.

The display panel DP may include a display area DA and a non-display area NDA. The display area DA may be an area capable of displaying an image by emitting light. A plurality of pixels PX for generating the image may be disposed in the display area DA. The non-display area NDA may be an area not displaying the image. The non-display area NDA may be disposed around the display area DA. In an embodiment, the non-display area NDA may surround an entirety of the display area DA, for example. Signal lines or driving circuits for applying signals to the display area DA may be disposed in the non-display area NDA.

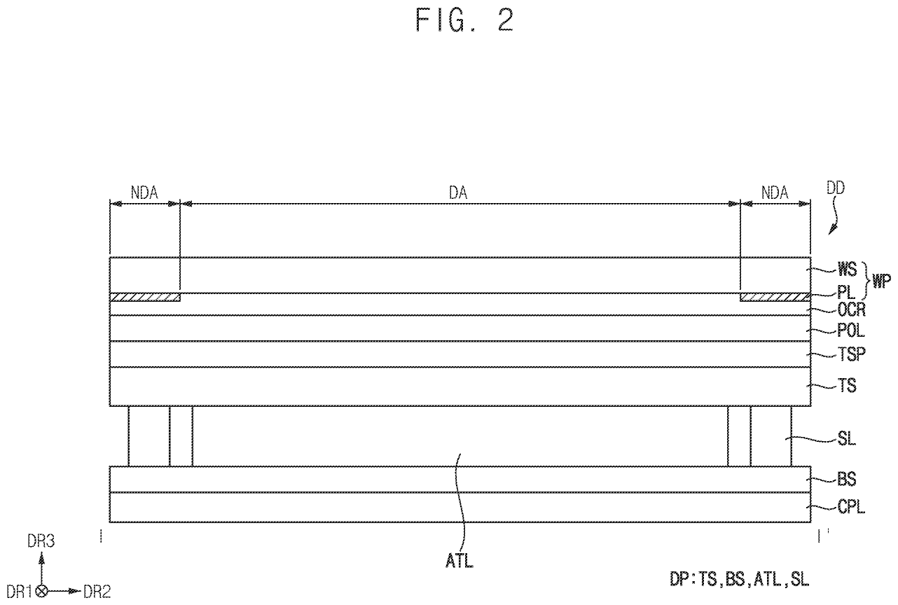

The driving chip IC may be disposed in the non-display area NDA. The driving chip IC may include an integrated circuit that drives the display panel DP. The integrated circuit may include an integrated circuit for display and/or an integrated circuit for a touch member (e.g., a touch member TSP of FIG. 2). The driving chip IC may be directly disposed (e.g., mounted) on a protruding area of the lower substrate BS protruding from the upper substrate TS.

FIG. 2 is a cross-sectional view taken along line I-I′ of FIG. 1. In an embodiment, FIG. 2 schematically illustrates a cross-sectional view of the display device DD, for example.

Referring to FIG. 2, the display device DD may include the display panel DP, a touch member TSP, an anti-reflection member POL, a window member WP, and a cover panel CPL. Here, the display panel DP may include the upper substrate TS, the lower substrate BS, an active element layer ATL, and a sealing member SL. The window member WP may include a window substrate WS and a printed layer PL.

The lower substrate BS may support the active element layer ATL disposed on the lower substrate BS. The lower substrate BS may include a transparent or opaque material. The lower substrate BS may include or consist of a transparent resin substrate. A polyimide substrate may be mentioned in an embodiment of the transparent resin substrate. In this case, the polyimide substrate may include a first organic layer, a first barrier layer, a second organic layer, etc. In an alternative embodiment, the lower substrate BS may include a quartz substrate, a synthetic quartz substrate, a calcium fluoride substrate, an F-doped quartz substrate, a sodalime glass substrate, a non-alkali glass substrate, etc. These may be used alone or in any combinations with each other.

The upper substrate TS may face the lower substrate BS and may be spaced apart from the lower substrate BS. The upper substrate TS may protect the active element layer ATL from external moisture and air. The upper substrate TS may include or consist of a transparent resin substrate. A polyimide substrate may be mentioned in an embodiment of the transparent resin substrate. In an alternative embodiment, the upper substrate TS may include at least one inorganic encapsulation layer and at least one organic encapsulation layer. In an embodiment, the inorganic encapsulation layer may include a silicon oxide, a silicon nitride, a silicon oxynitride, etc., for example. In addition, the organic encapsulation layer may include a polymer cured material such as polyacrylate.

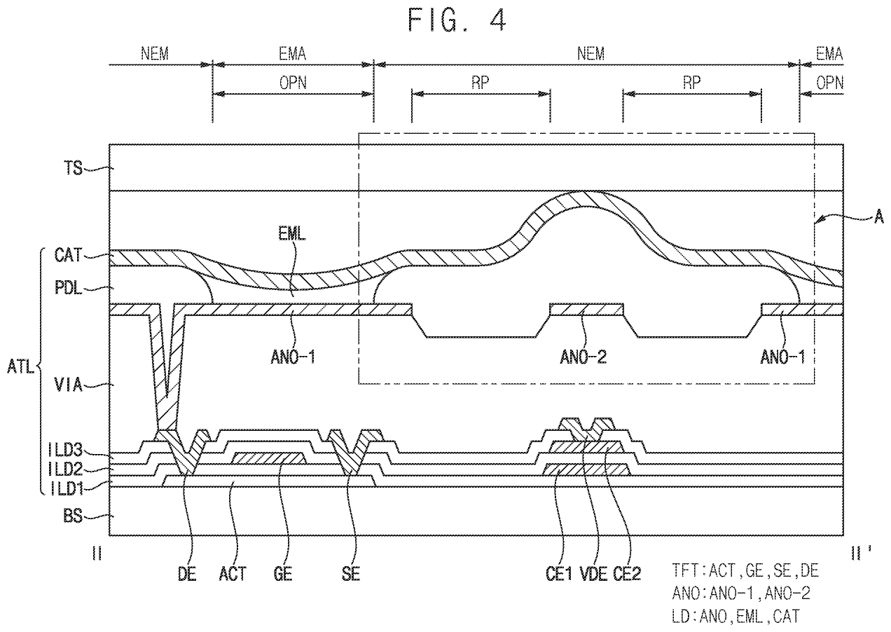

The active element layer ATL may be disposed between the lower substrate BS and the upper substrate TS. The active element layer ATL may be disposed on the lower substrate BS. The active element layer ATL may include a light-emitting element (e.g., a light-emitting element LD of FIG. 4) and a thin film transistor (e.g., a thin film transistor TFT of FIG. 4) driving the light-emitting element. This will be described later with reference to FIG. 4.

The sealing member SL may be disposed between the lower substrate BS and the upper substrate TS. In an embodiment, the sealing member SL may be disposed in the non-display area NDA of the display device DD to surround the display area DA, for example. The sealing member SL may couple the lower substrate BS and the upper substrate TS, and may seal the active element layer ATL together with the lower substrate BS and the upper substrate TS. The sealing member SL may include a frit, but the disclosure is not limited thereto.

The touch member TSP may be disposed on the display panel DP. The touch member TSP may detect a touch input. The touch member TSP may be disposed on the upper substrate TS. The touch member TSP may include a plurality of touch electrodes. The touch member TSP may be provided as a separate panel or film from the display panel DP and may be attached to the display panel DP. In an alternative embodiment, the touch member TSP may be provided in the form of a touch layer inside the display panel DP.

The anti-reflection member POL may be disposed on the touch member TSP. When external light may be incident on the display device DD, the external light may be reflected from various electrodes or wires included in the display panel DP. The anti-reflection member POL may prevent the external light from being recognized as the external light is reflected. When the touch member TSP is omitted, the anti-reflection member POL may be attached to the upper substrate TS.

The window member WP may be disposed on the anti-reflection member POL. The window member WP may cover and protect the display panel DP. The window member WP may include the window substrate WS and the printed layer PL. The window member WP may be attached to one surface of the display panel DP through a transparent bonding layer OCR including an optically clear adhesive (“OCA”), an optically clear resin, etc. When the display device DD includes the anti-reflection member POL, the window member WP may be attached to an upper surface of the anti-reflection member POL.

The window substrate WS may include or consist of a transparent material. In an embodiment, the window substrate WS may include glass or plastic, for example. The printed layer PL may be disposed on the window substrate WS. The printed layer PL may be disposed on the edge of the window substrate WS in the non-display area NDA. The printed layer PL may be also referred to as a light-blocking layer.

The cover panel CPL may be disposed below the display panel DP. The cover panel CPL may protect the display panel DP from impact. The cover panel CPL may include a metal material to dissipate heat. In an embodiment, the cover panel CPL may include aluminum (Al), copper (Cu), etc., for example. These may be used alone or in any combinations with each other.

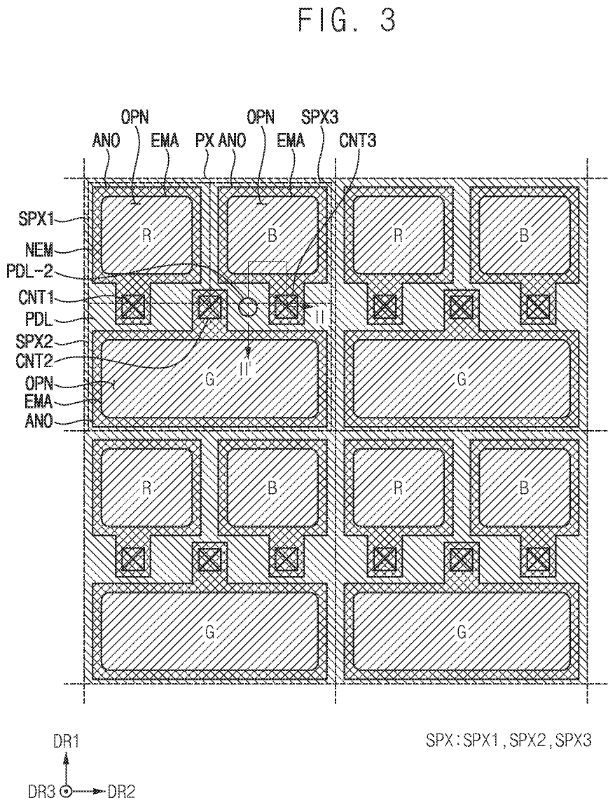

FIG. 3 is a plan view illustrating a pixel arrangement of the display device of FIG. 1.

Referring to FIG. 3, the plurality of pixels PX for generating the image may be disposed in the display area (e.g., the display area DA of FIG. 1) of the display device DD. The pixels PX may be arranged in a matrix form along the first and second directions DR1 and DR2.

Each pixel PX may include a plurality of sub-pixels SPX emitting different colors. In an embodiment, each pixel PX may include a first sub-pixel SPX1 emitting red light, a second sub-pixel SPX2 emitting green light, and a third sub-pixel SPX3 emitting blue light, for example.

Each sub-pixel SPX may include an emission area EMA and a non-emission area NEM. The image may be generated by combining light emitted from each of the pixels PX in the emission area EMA. The non-emission area NEM may be disposed around the emission area EMA. The non-emission area NEM of one sub-pixel SPX may contact the non-emission area NEM of an adjacent sub-pixel SPX. The emission area EMA of each neighboring sub-pixel SPX may be divided by the non-emission area NEM.

Planar shape of the emission area EMA of each sub-pixel SPX in each pixel PX may not be same. In an embodiment, the planar shape of the emission area EMA of the first sub-pixel SPX1 may be substantially the same as the planar shape of the emission area EMA of the third sub-pixel SPX3, for example. The planar shape of the emission area EMA of the first sub-pixel SPX1 may be different from the planar shape of the emission area EMA of the second sub-pixel SPX2. In addition, the size of the emission area EMA of the first sub-pixel SPX1 and the size of the emission area EMA of the third sub-pixel SPX3 may be smaller than the size of the emission area EMA of the second sub-pixel SPX2.

A lower electrode ANO and a pixel defining layer PDL may be disposed on one surface of the lower substrate (e.g., the lower substrate BS of FIG. 4). Each lower electrode ANO may be electrically connected to a thin film transistor (e.g., the thin film transistor TFT of FIG. 4) through a first contact hole CNT1, a second contact hole CNT2, or a third contact hole CNT3.

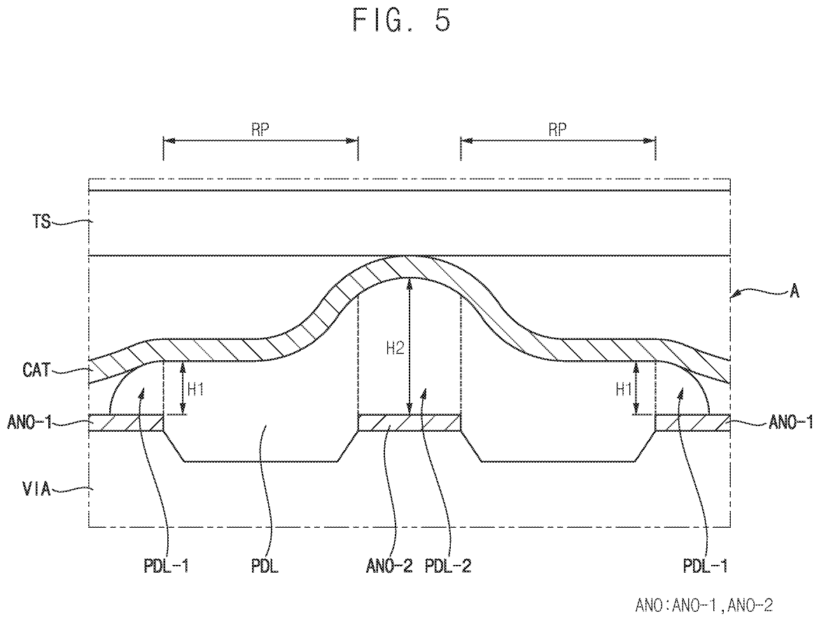

The pixel defining layer PDL may be disposed along a boundary of the sub-pixel SPX. The pixel defining layer PDL may be disposed on the lower electrode ANO and a via insulating layer (e.g., a via insulating layer VIA of FIG. 4). The pixel defining layer PDL may define an opening OPN exposing at least a part of an upper surface of the lower electrode ANO. The non-emission area NEM and the emission area EMA may be divided by the opening OPN. The pixel defining layer PDL may include a first area (e.g. a first area PDL-1 of FIG. 5) and a second area PDL-2. The second area PDL-2 of the pixel defining layer PDL may serve as a spacer. This will be described later with reference to FIGS. 4 and 5.

FIG. 4 is a cross-sectional view taken along line II-II′ of FIG. 3. FIG. 5 is an enlarged cross-sectional view of area ‘A’ of FIG. 4.

Referring to FIGS. 1 and 4, the display device DD (refer to FIGS. 1 and 2) may include the lower substrate BS, the active element layer ATL, a first capacitor electrode CE1, a second capacitor electrode CE2, a power electrode VDE, and the upper substrate TS. Here, the active element layer ATL may include a thin film transistor TFT, a first insulating layer ILD1, a second insulating layer ILD2, a third insulating layer ILD3, a via insulating layer VIA, the pixel defining layer PDL, and a light-emitting element LD. Here, the thin film transistor TFT may include an active layer ACT, a gate electrode GE, a source electrode SE, and a drain electrode DE. The light-emitting element LD may include the lower electrode ANO, a light-emitting layer EML, and an upper electrode CAT.

The lower substrate BS may include a transparent or opaque material. The lower substrate BS may include or consist of a transparent resin substrate. In an embodiment, the transparent resin substrate that may be used as the lower substrate BS may be a polyimide substrate, for example.

A buffer layer may be disposed on the lower substrate BS. The buffer layer may prevent diffusion of metal atoms or impurities from the lower substrate BS to an upper structure (e.g., the thin film transistor TFT, the light-emitting element LD, etc.). In addition, the buffer layer may obtain the substantially uniform active layer ACT by controlling a heat transfer rate during a crystallization process for forming the active layer ACT. Also, the buffer layer may serve to improve flatness of the surface of the lower substrate BS when the surface of the lower substrate BS is not uniform. In an embodiment, the buffer layer may include an organic insulating material and/or an inorganic insulating material, for example. In an alternative embodiment, the buffer layer may be omitted.

The active layer ACT may be disposed on the lower substrate BS. The active layer ACT may include an oxide semiconductor, a silicon semiconductor, an organic semiconductor, etc. In an embodiment, the oxide semiconductor may include indium (In), gallium (Ga), tin (Sn), zirconium (Zr), vanadium (V), hafnium (Hf), cadmium (Cd), germanium (Ge), chromium (Cr), titanium (Ti), zinc (Zn), etc., for example. These may be used alone or in any combinations with each other. The silicon semiconductor may include amorphous silicon, polycrystalline silicon, etc. The active layer ACT may include a source area, a drain area, and a channel area disposed between the source area and the drain area.

The first insulating layer ILD1 may be disposed on the lower substrate BS in the emission area EMA and the non-emission area NEM. The first insulating layer ILD1 may cover the active layer ACT on the lower substrate BS and may be disposed along the profile of the active layer ACT with a uniform thickness. In an alternative embodiment, the first insulating layer ILD1 may sufficiently cover the active layer ACT on the lower substrate BS and may have a substantially flat upper surface without creating a step difference around the active layer ACT. The first insulating layer ILD1 may include a silicon compound or a metal oxide, etc. In an embodiment, the first insulating layer ILD1 may include the silicon compound such as silicon oxide (SiOₓ), silicon nitride (SiNₓ), silicon carbide (SiCₓ), silicon oxynitride (SiOₓN_{y}), silicon oxycarbide (SiOₓC_{y}), etc., for example. These may be used alone or in any combinations with each other.

The gate electrode GE may be disposed on the first insulating layer ILD1. The gate electrode GE may overlap the channel area of the active layer ACT. In an embodiment, the gate electrode GE may include a metal, a metal alloy, a metal nitride, a conductive metal oxide, a transparent conductive material, etc., for example. In embodiments, materials that may be used as the gate electrode GE may include silver (Ag), an alloy including or consisting of silver, molybdenum (Mo), an alloy including or consisting of molybdenum, aluminum (Al), an alloy including or consisting of aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (“ITO”), indium zinc oxide (“IZO”), etc. These may be used alone or in any combinations with each other. In addition, the gate electrode may include or consist of a single layer or multiple layers in combination with each other.

The first capacitor electrode CE1 may be disposed on the first insulating layer ILD1 in the non-emission area NEM. In an embodiment, the first capacitor electrode CE1 may include a metal, a metal alloy, a metal nitride, a conductive metal oxide, a transparent conductive material, etc., for example. These may be used alone or in any combinations with each other. The first capacitor electrode CE1 may include the same material as that of the gate electrode GE and may be disposed in the same layer as the gate electrode GE.

The second insulating layer ILD2 may be disposed on the first insulating layer ILD1 in the emission area EMA and the non-emission area NEM. The second insulating layer ILD2 may cover each of the gate electrode GE and the first capacitor electrode CE1 and may be disposed along the profile of the gate electrode GE and the first capacitor electrode CE1 with a uniform thickness. In an alternative embodiment, the second insulating layer ILD2 may have a substantially flat upper surface without creating a step difference around each of the gate electrode GE and the first capacitor electrode CE1 on the first insulating layer ILD1. In an embodiment, the second insulating layer ILD2 may include a silicon compound, a metal oxide, etc., for example.

The second capacitor electrode CE2 may be disposed on the second insulating layer ILD2 in the non-emission area NEM. In an embodiment, the second capacitor electrode CE2 may include a metal, a metal alloy, a metal nitride, a conductive metal oxide, a transparent conductive material, etc., for example. These may be used alone or in any combinations with each other.

The third insulating layer ILD3 may be disposed on the second insulating layer ILD2 in the emission area EMA and the non-emission area NEM. The third insulating layer ILD3 may cover the second capacitor electrode CE2 and may be disposed along the profile of the second capacitor electrode CE2 with a uniform thickness. In an embodiment, the third insulating layer ILD3 may include a silicon compound, a metal oxide, etc., for example.

The source electrode SE and the drain electrode DE may be disposed on the third insulating layer ILD3. The source electrode SE may be connected to the source area of the active layer ACT through a contact hole defined by removing a first part of the first insulating layer ILD1, the second insulating layer ILD2, and the third insulating layer ILD3. The drain electrode DE may be connected to the drain area of the active layer ACT through a contact hole defined by removing a second part of the first insulating layer ILD1, the second insulating layer ILD2, and the third insulating layer ILD3. In an embodiment, each of the source electrode SE and the drain electrode DE may include a metal, a metal alloy, a metal nitride, a conductive metal oxide, a transparent conductive material, etc., for example. These may be used alone or in any combinations with each other.

The power electrode VDE may be disposed on the third insulating layer ILD3 in the non-emission area NEM. The power electrode VDE may be connected to the second capacitor electrode CE2 through a contact hole defined by removing a third part of the third insulating layer ILD3. In an embodiment, the power electrode VDE may include a metal, a metal alloy, a metal nitride, a conductive metal oxide, a transparent conductive material, etc., for example. These may be used alone or in any combinations with each other. The power electrode VDE may include the same material as that of the source electrode SE and the drain electrode DE, and may be disposed in the same layer as the source electrode SE and the drain electrode DE.

The via insulating layer VIA may be disposed on the third insulating layer ILD3 in the emission area EMA and the non-emission area NEM. In an embodiment, the via insulating layer VIA may be disposed on the third insulating layer ILD3 with a relatively thick thickness to sufficiently cover the source electrode SE, the drain electrode DE, and the power electrode VDE, for example.

The via insulating layer VIA may include an organic insulating material or an inorganic insulating material. In an embodiment, the via insulating layer VIA may include an organic insulating material. In an embodiment, the via insulating layer VIA may include photoresist, polyacryl-based resin, polyimide-based resin, polyamide-based resin, siloxane-based resin, acryl-based resin, epoxy-based resin, etc., for example. These may be used alone or in any combinations with each other. In an embodiment, the via insulating layer VIA may include a positive photosensitive material.

In an embodiment, the via insulating layer VIA may define a groove RP. In other words, the via insulating layer VIA may define the groove RP in the non-emission area NEM. That is, the groove RP may be defined as a part of an upper surface of the via insulating layer VIA recessed toward the lower substrate BS.

The lower electrode ANO may be disposed on the via insulating layer VIA in the emission area EMA and the non-emission area NEM. In an embodiment, the lower electrode ANO may include a metal, a metal alloy, a metal nitride, a conductive metal oxide, a transparent conductive material, etc., for example. These may be used alone or in any combinations with each other.

In an embodiment, the lower electrode ANO may include a first part ANO-1 and a second part ANO-2. The first part ANO-1 of the lower electrode ANO may be connected to the drain electrode DE through the contact hole of the via insulating layer VIA. Accordingly, the first part ANO-1 of the lower electrode ANO may be electrically connected to the thin film transistor TFT. The second part ANO-2 of the lower electrode ANO may be spaced apart from the first part ANO-1 of the lower electrode ANO and may be surrounded by the groove RP in a plan view. The first part ANO-1 of the lower electrode ANO may overlap the emission area EMA and the second part ANO-2 of the lower electrode ANO may overlap the non-emission area NEM.

The pixel defining layer PDL may be disposed on the via insulating layer VIA in the non-emission area NEM. The pixel defining layer PDL may cover an edge of the lower electrode ANO and may define an opening OPN exposing at least a part of an upper surface of the lower electrode ANO.

Referring further to FIG. 5, the pixel defining layer PDL may include a first area PDL-1 and a second area PDL-2. In the first area PDL-1, the pixel defining layer PDL may define the opening OPN and may cover at least a part of the first part ANO-1 of the lower electrode ANO. In the second area PDL-2, the pixel defining layer PDL may overlap the second part ANO-2 of the lower electrode ANO in a plan view. Also, the second area PDL-2 of the pixel defining layer PDL may not overlap the groove RP in a plan view. That is, the second area PDL-2 of the pixel defining layer PDL may be spaced apart from the groove RP.

The pixel defining layer PDL may fill the groove RP of the via insulating layer VIA. As the pixel defining layer PDL fills the groove RP of the via insulating layer VIA, the pixel defining layer PDL may have different heights depending on position with respect to the upper surface of the lower electrode ANO.

In an embodiment, a height H1 of the upper surface of the pixel defining layer PDL in the first area PDL-1 with respect to the upper surface of the lower electrode ANO may be less than about 1.0 micrometer (μm). In this case, the height H1 of the upper surface of the pixel defining layer PDL may be defined as the maximum height of the upper surface of the pixel defining layer PDL in the first area PDL-1. When the height H1 of the upper surface of the pixel defining layer PDL in the first area PDL-1 with respect to the upper surface of the lower electrode ANO exceeds about 1.0 μm, the thickness deviation of the light-emitting layer EML disposed in the opening OPN for each sub-pixel (e.g., the sub-pixel SPX of FIG. 3) may increase. Due to the thickness deviation, a stain defect of the display device DD may occur.

Also, in an embodiment, with respect to the upper surface of the lower electrode ANO, a height H2 of the upper surface of the pixel defining layer PDL in the second area PDL-2 may be greater than the height H1 of the upper surface of the pixel defining layer PDL in the first area PDL-1. That is, as the pixel defining layer PDL fills the groove RP of the via insulating layer VIA, the height H2 of the upper surface of the pixel defining layer PDL in the second area PDL-2 may be greater than the height H1 of the upper surface of the pixel defining layer PDL in the first area PDL-1. In an embodiment, the height H2 of the upper surface of the pixel defining layer PDL in the second area PDL-2 may be about 1.5 μm to about 2.0 μm, for example. Accordingly, the second area PDL-2 of the pixel defining layer PDL may serve as a spacer. That is, the second area PDL-2 of the pixel defining layer PDL may maintain a distance from a structure (e.g., the upper substrate TS) disposed on the pixel defining layer PDL. In addition, the second area PDL-2 of the pixel defining layer PDL may prevent sagging of a fine metal mask (“FMM”).

The pixel defining layer PDL may include an organic insulating material or an inorganic insulating material. In an embodiment, a surface of the pixel defining layer PDL may have liquid repellency. That is, the pixel defining layer PDL may further include a liquid repellent material. In an embodiment, the liquid repellent material may include a fluorine-based compound, a siloxane-based compound, etc., for example. The liquid repellent material may be disposed on upper and side surfaces of the pixel defining layer PDL. That is, the liquid repellent material may cover the surface of the pixel defining layer PDL. As the pixel defining layer PDL has liquid repellency, the light-emitting layer EML may be more stably formed in the opening OPN. That is, reliability of the display device DD may be improved. In another embodiment, the pixel defining layer PDL may include an inorganic material including a light blocking material with black color or an organic material including the light-blocking material with the black color.

The light-emitting layer EML may be disposed in the opening OPN of the pixel defining layer PDL. The light-emitting layer EML may be formed using at least one of light-emitting materials capable of emitting red light, green light, and blue light according to the type of the sub-pixel. In an alternative embodiment, the light-emitting layer EML may emit white light as a whole by stacking a plurality of light-emitting materials capable of generating different color lights such as red light, green light, and blue light.

The light-emitting layer EML may be formed by inkjet printing. Accordingly, an upper surface of the light-emitting layer EML may have a concave cross-sectional shape toward the lower substrate BS. In other words, a thickness of the light-emitting layer EML may increase from a center of the light-emitting layer EML toward the pixel defining layer PDL.

The upper electrode CAT may be disposed on the light-emitting layer EML and the pixel defining layer PDL. Specifically, the upper electrode CAT may cover the upper surface of the light-emitting layer EML and the upper surface of the pixel defining layer PDL. The upper electrode CAT may be conformally formed with respect to a lower structure to reflect a step difference of the lower structure. That is, the upper electrode CAT may be disposed along the profile of the light-emitting layer EML and the pixel defining layer PDL with a uniform thickness. In an embodiment, the upper electrode CAT may include a metal, a metal alloy, a metal nitride, a conductive metal oxide, a transparent conductive material, etc., for example. These may be used alone or in any combinations with each other. Accordingly, the lower electrode ANO, the light-emitting layer EML, and the upper electrode CAT may constitute the light-emitting element LD.

The upper substrate TS may be disposed on the upper electrode CAT. The upper substrate TS may protect the active element layer ATL from external moisture and air. The upper substrate TS may include or consist of a transparent resin substrate. A polyimide substrate may be an embodiment of the transparent resin substrate. In an alternative embodiment, the upper substrate TS may include at least one inorganic encapsulation layer and at least one organic encapsulation layer. In an embodiment, the inorganic encapsulation layer may include a silicon oxide, a silicon nitride, a silicon oxynitride, etc., for example. In addition, the organic encapsulation layer may include a polymer cured material such as polyacrylate.

However, although the display device DD of the disclosure is described by limiting the organic light-emitting display device (“OLED”), the configuration of the disclosure is not limited thereto. In other embodiments, the display device DD may include various other display devices such as a liquid crystal display device (“LCD”), a field emission display device (“FED”), a plasma display device (“PDP”), an electrophoretic display device (“EPD”), an inorganic light-emitting display device (“ILED”), or a quantum dot display device.

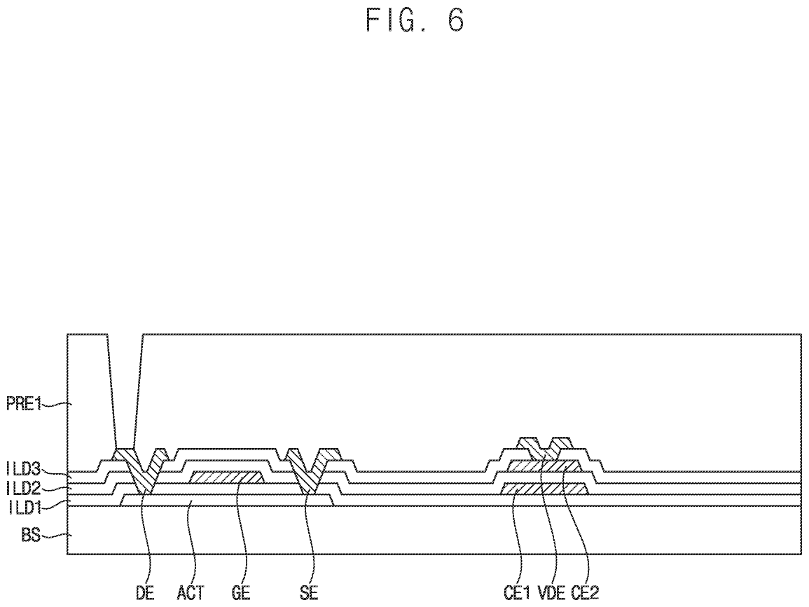

FIGS. 6, 7, 8, 9, 10, 11, and 12 are cross-sectional views illustrating an embodiment of a method of manufacturing the display device. Hereinafter, description of method of forming the thin film transistor TFT, the first insulating layer ILD1, the second insulating layer ILD2, the third insulating layer ILD3, the first capacitor electrode CE1, the second capacitor electrode CE2, and the power electrode VDE on the lower substrate BS is omitted.

Referring to FIG. 6, a first preliminary layer PRE1 may be formed on the lower substrate BS. Specifically, the first preliminary layer PRE1 may be formed on the third insulating layer ILD3 to cover the source electrode SE, the drain electrode DE, and the power electrode VDE. The first preliminary layer PRE1 may define a contact hole exposing an upper surface of the drain electrode DE. The first preliminary layer PRE1 may include or consist of an organic insulating material or an inorganic insulating material.

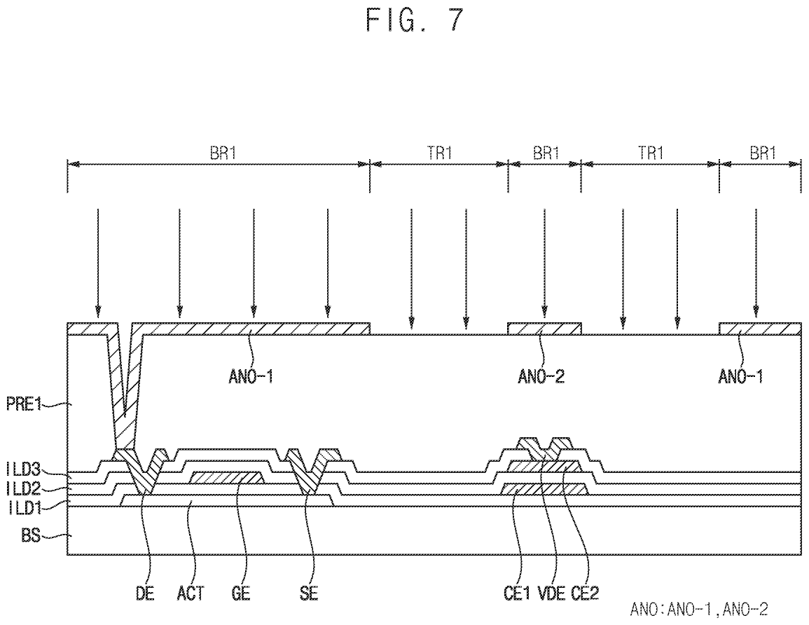

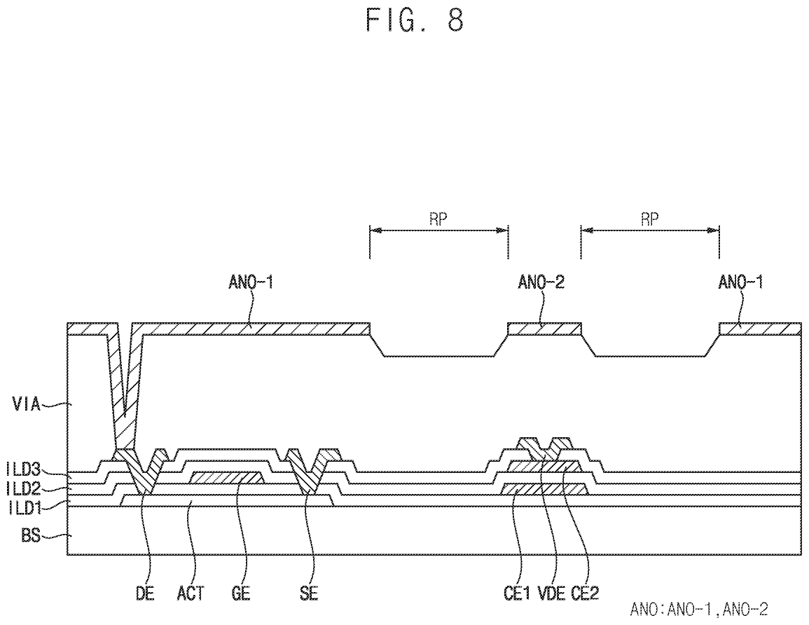

Referring to FIGS. 7 and 8, the lower electrode ANO may be formed on the first preliminary layer PRE1. The lower electrode ANO may include the first part ANO-1 and the second part ANO-2. The first part ANO-1 of the lower electrode ANO may be connected to the drain electrode DE through the contact hole of the first preliminary layer PRE1. The second part ANO-2 of the lower electrode ANO may be spaced apart from the first part ANO-1 of the lower electrode ANO. The lower electrode ANO may be formed using a metal, a metal alloy, a metal nitride, a conductive metal oxide, a transparent conductive material, etc. These may be used alone or in any combinations with each other.

In an embodiment, the first preliminary layer PRE1 may include an organic material including a photosensitive material. In an embodiment, the first preliminary layer PRE1 may include a positive photosensitive material, for example. That is, by the lower electrode ANO as a first photomask, the first preliminary layer PRE1 may be patterned through exposure and development. Accordingly, the via insulating layer VIA may be formed. The first photomask may be divided into a light-blocking area BR1 in which the lower electrode ANO is disposed and a light-transmitting area TR1 in which the lower electrode ANO is not disposed. The light transmittance of the light-blocking area BR1 may be smaller than the light transmittance of the light-transmitting area TR1.

The lower electrode ANO may block light provided from the outside. Accordingly, the light may not reach the light-blocking area BR1 of the first preliminary layer PRE1. The light may reach the light-transmitting area TR1 of the first preliminary layer PRE1 on which the lower electrode ANO is not disposed.

When the first preliminary layer PRE1 includes the positive photosensitive material, the light-blocking part may maintain a cured state and may not be easily soluble in a developer. At this time, by a predetermined developer, one part of the first preliminary layer PRE1 may be selectively removed according to a change in chemical characteristics of a part exposed to light and a part not exposed to light. Accordingly, the first preliminary layer PRE1 may be patterned by selectively removing the first preliminary layer PRE1 in the light-transmitting area TR1. Accordingly, the via insulating layer VIA may be formed. That is, the via insulating layer VIA may define the groove RP. The groove RP may be defined as a part of the upper surface of the via insulating layer VIA recessed toward the lower substrate BS.

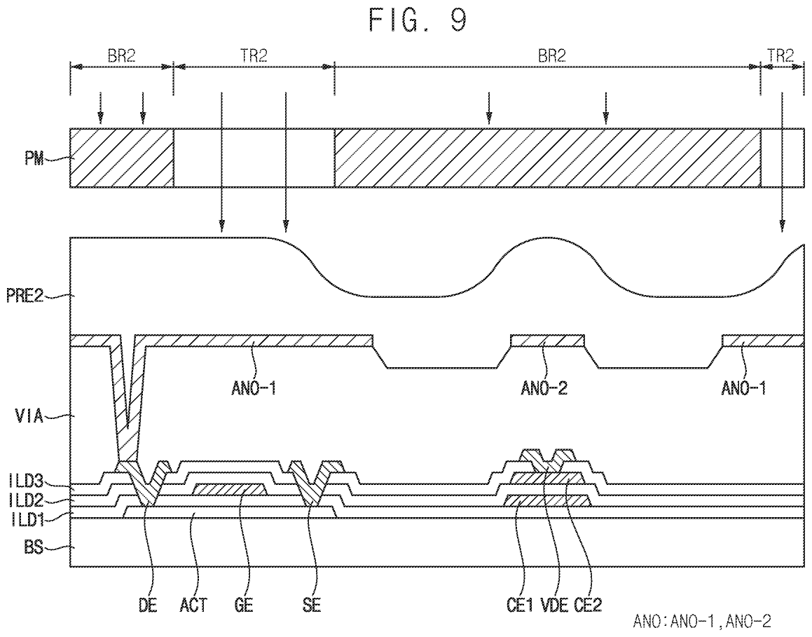

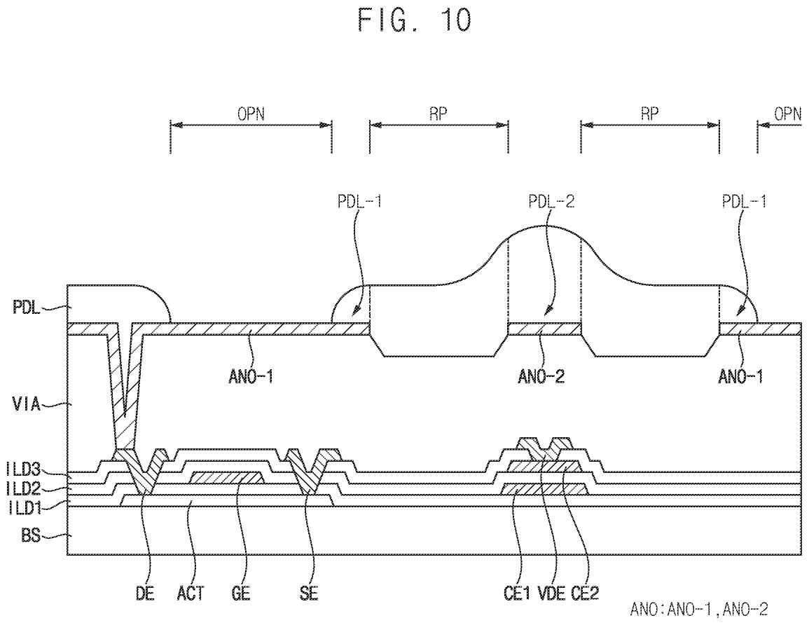

Referring to FIGS. 9 and 10, a second preliminary layer PRE2 may be formed on the via insulating layer VIA and the lower electrode ANO. The second preliminary layer PRE2 may cover the lower electrode ANO and fill the groove RP of the via insulating layer VIA. In this case, the second preliminary layer PRE2 may be conformally formed with respect to a lower structure to reflect a step difference of the lower structure. That is, the second preliminary layer PRE2 may be disposed along the profile of the lower electrode ANO and the groove RP with a uniform thickness. The second preliminary layer PRE2 may be formed using an organic insulating material or an inorganic insulating material.

In an embodiment, the second preliminary layer PRE2 may include an organic material including a photosensitive material. In an embodiment, the second preliminary layer PRE2 may include a positive photosensitive material, for example. That is, by the second photomask PM, the second preliminary layer PRE2 may be patterned through exposure and development. Accordingly, the pixel defining layer PDL may be formed. The second photomask PM may be divided into a light-blocking area BR2 and a light-transmitting area TR2 according to light transmittance. The light transmittance of the light-blocking area BR2 may be smaller than the light transmittance of the light-transmitting area TR2.

In the light-blocking area BR2, the second photomask PM may block light provided from the outside to prevent the light from reaching the light-blocking area BR2 of the second preliminary layer PRE2. In the light-transmitting area TR2, the second photomask PM may allow the light to reach the light-transmitting area TR2 of the second preliminary layer PRE2.

When the second preliminary layer PRE2 includes the positive photosensitive material, the light-blocking part may maintain a cured state and may not be easily soluble in a developer. At this time, by a predetermined developer, one part of the second preliminary layer PRE2 may be selectively removed according to a change in chemical characteristics of a part exposed to light and a part not exposed to light. Accordingly, the second preliminary layer PRE2 may be patterned by selectively removing the second preliminary layer PRE2 in the light-transmitting area TR2. Accordingly, the pixel defining layer PDL may be formed. That is, the pixel defining layer PDL may define the opening OPN exposing at least a part of the upper surface of the lower electrode ANO. In addition, the pixel defining layer PDL may include the first area PDL-1 defining the opening OPN and covering at least a part of the first part ANO-1 of the lower electrode ANO and the second area PDL-2 overlapping the second part ANO-2 of the lower electrode ANO in a plan view.

The pixel defining layer PDL may fill the groove RP of the via insulating layer VIA. As the pixel defining layer PDL fills the groove RP of the via insulating layer, the pixel defining layer PDL may have different heights depending on position with respect to the upper surface of the lower electrode ANO.

In an embodiment, a height of the upper surface of the pixel defining layer PDL in the first area PDL-1 with respect to the upper surface of the lower electrode ANO may be less than about 1.0 μm. In this case, the height of the upper surface may be defined as the maximum height of the upper surface of the pixel defining layer PDL in the first area PDL-1. Accordingly, the thickness deviation of the light-emitting layer EML disposed in the opening OPN for each sub-pixel (e.g., the sub-pixel SPX of FIG. 3) may be reduced. As a result, stain defects of the display device may be improved.

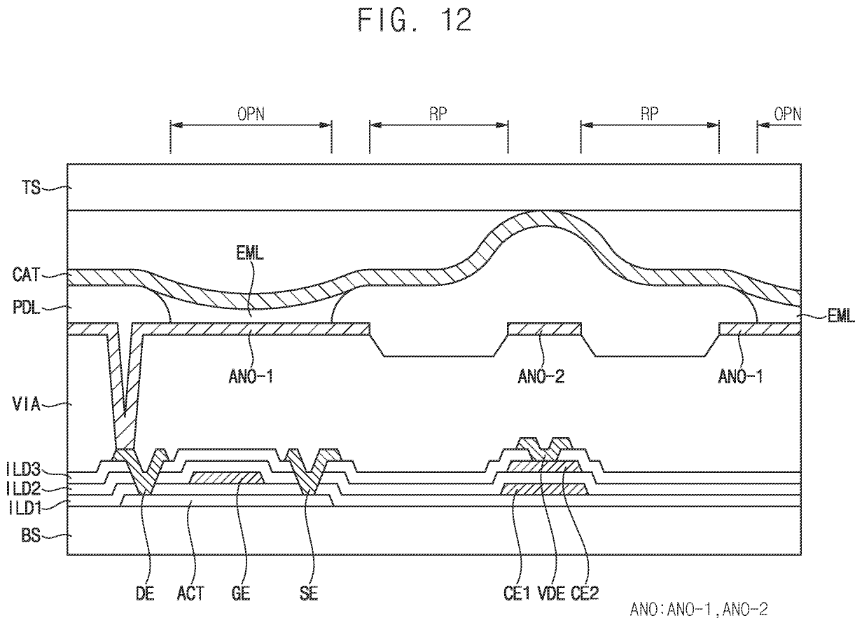

In an embodiment, with respect to the upper surface of the lower electrode ANO, a height of the upper surface of the pixel defining layer PDL in the second area PDL-2 may be greater than the height of the upper surface of the pixel defining layer PDL in the first area PDL-1. Accordingly, the second area PDL-2 of the pixel defining layer PDL may serve as a spacer. That is, the second area PDL-2 of the pixel defining layer PDL may maintain a distance from a structure (e.g., the upper substrate TS of FIG. 12) disposed on the pixel defining layer PDL. In addition, the second area PDL-2 of the pixel defining layer PDL may prevent sagging of the fine metal mask.

The pixel defining layer PDL may include an organic insulating material or an inorganic insulating material. In an embodiment, the surface of the pixel defining layer PDL may have liquid repellency. That is, the pixel defining layer PDL may include a liquid repellent material. In another embodiment, the pixel defining layer PDL may include an inorganic material including a light blocking material with black color or an organic material including the light-blocking material with the black color.

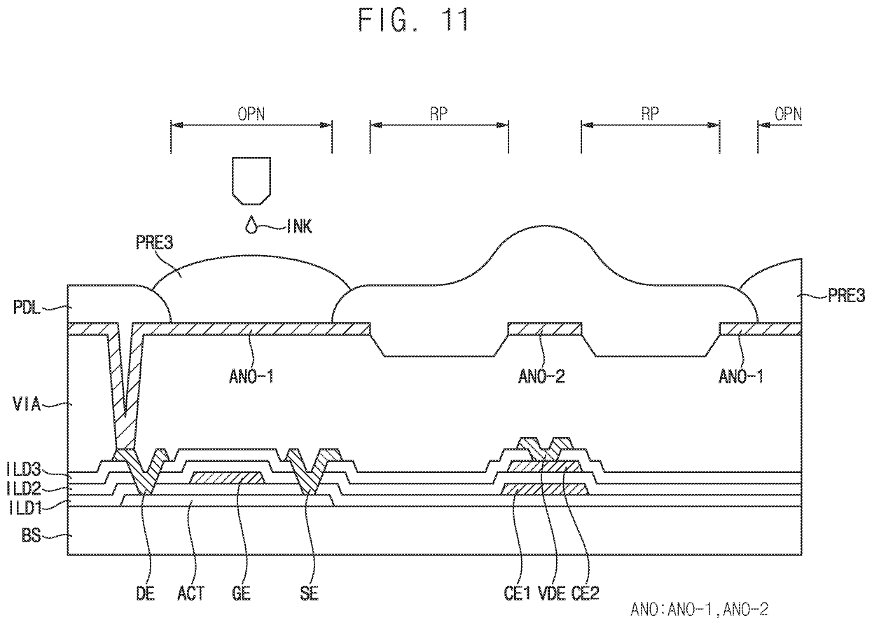

Referring to FIGS. 11 and 12, a third preliminary layer PRE3 may be formed in the opening OPN of the pixel defining layer PDL. In this case, the third preliminary layer PRE3 may be formed through an inkjet printing method using ink INK. As the pixel defining layer PDL has liquid repellency, surface bonding strength between the third preliminary layer PRE3 and the pixel defining layer PDL may be reduced. In this case, a contact angle between the third preliminary layer PRE3 and the pixel defining layer PDL may increase. Therefore, the third preliminary layer PRE3 may not overflow onto the upper surface of the pixel defining layer PDL and may be more stably disposed on the lower electrode ANO exposed by the pixel defining layer PDL.

After inkjet printing the third preliminary layer PRE3, the light-emitting layer EML may be formed by drying the third preliminary layer PRE3. A solvent of the third preliminary layer PRE3 may be evaporated through the drying process. As a result, the volume of the third preliminary layer PRE3 may be reduced so that the light-emitting layer EML illustrated in FIG. 11 may be formed. That is, the upper surface of the light-emitting layer EML may be formed to have a concave cross-sectional shape toward the lower substrate BS. In other words, the thickness of the light-emitting layer EML may increase from a center of the light-emitting layer EML toward the pixel defining layer PDL. The spray amount of the third preliminary layer PRE3 may be determined in consideration of surface tension and volume shrinkage after drying.

The upper electrode CAT may be formed on the light-emitting layer EML and the pixel defining layer PDL. Specifically, the upper electrode CAT may be formed to cover the upper surface of the light-emitting layer EML and the upper surface of the pixel defining layer PDL. In this case, the upper electrode CAT may be formed with a uniform thickness along the profile of the light-emitting layer EML and the pixel defining layer PDL. In an embodiment, the upper electrode CAT may be formed using a metal, a metal alloy, a metal nitride, a conductive metal oxide, a transparent conductive material, etc. These may be used alone or in any combinations with each other, for example.

The upper substrate TS may be formed on the upper electrode CAT. The upper substrate TS may be a transparent plate or a transparent film. The upper substrate TS may be formed to contact the upper electrode CAT. However, the disclosure is not limited thereto.

The disclosure may be applied to various display devices. In an embodiment, the disclosure may be applied to various display devices such as display devices for vehicles, ships and aircraft, portable communication devices, display devices for exhibition or information transmission, medical display devices or the like, for example.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the inventive concept. Accordingly, all such modifications are intended to be included within the scope of the inventive concept as defined in the claims. Therefore, it is to be understood that the foregoing is illustrative of various embodiments and is not to be construed as limited to the illustrative embodiments disclosed, and that modifications to the disclosed embodiments, as well as other embodiments, are intended to be included within the scope of the appended claims.

What is claimed is:

1. A display device comprising:
a substrate;
a via insulating layer disposed on the substrate and defining a groove;
a lower electrode disposed on the via insulating layer and spaced apart from the groove in a plan view;
a pixel defining layer disposed on the via insulating layer, defining an opening exposing at least a part of an upper surface of the lower electrode, and filling the groove; and
a light-emitting layer disposed in the opening of the pixel defining layer.

2. The display device of claim 1, wherein the lower electrode includes:
a first part including an upper surface exposed by the opening; and
a second part spaced apart from the first part and surrounded by the groove in the plan view.

3. The display device of claim 2, wherein the pixel defining layer includes:
a first area defining the opening and covering at least a part of the first part of the lower electrode; and
a second area overlapping the second part of the lower electrode in the plan view.

4. The display device of claim 3, wherein with respect to the upper surface of the lower electrode, a height of an upper surface of the pixel defining layer in the second area is greater than a height of the upper surface of the pixel defining layer in the first area.

5. The display device of claim 3, wherein with respect to the upper surface of the lower electrode, a height of an upper surface of the pixel defining layer in the first area is less than about 1.0 micrometer.

6. The display device of claim 1, wherein a surface of the pixel defining layer has liquid repellency.

7. The display device of claim 1, wherein the pixel defining layer includes an inorganic material including a light blocking material with black color or an organic material including the light blocking material with the black color.

8. The display device of claim 1, wherein an upper surface of the light-emitting layer has a concave cross-sectional shape toward the substrate.

9. The display device of claim 1, wherein the via insulating layer includes a positive photosensitive material.

10. A method for manufacturing a display device, the method comprising:
forming a first preliminary layer on a substrate;
forming a lower electrode on the first preliminary layer;
forming a via insulating layer defining a groove by patterning the first preliminary layer using the lower electrode as a mask;
forming a second preliminary layer on the lower electrode and the via insulating layer to cover the lower electrode and fill the groove; and
forming a pixel defining layer defining an opening exposing at least a part of an upper surface of the lower electrode by patterning the second preliminary layer through a mask.

11. The method of claim 10, further comprising:
forming a light-emitting layer in the opening of the pixel defining layer after the forming the pixel defining layer, wherein the light-emitting layer is formed through an inkjet printing method.

12. The method of claim 11, wherein an upper surface of the light-emitting layer is formed to have a concave cross-sectional shape toward the substrate.

13. The method of claim 10, wherein each of the first preliminary layer and the second preliminary layer includes a positive photosensitive material.

14. The method of claim 10, wherein a surface of the pixel defining layer has liquid repellency.

15. The method of claim 10, wherein the pixel defining layer includes an inorganic material including a light blocking material with black color or an organic material including the light-blocking material with the black color.

16. The method of claim 10, wherein in the forming of the second preliminary layer, the second preliminary layer is formed along the profile of the lower electrode and the groove.

17. The method of claim 10, wherein the lower electrode includes a first part including an upper surface exposed by the opening and a second part spaced apart from the first part and surrounded by the groove in a plan view, and
the pixel defining layer includes a first area defining the opening and covering at least a part of the first part of the lower electrode and a second area overlapping the second part of the lower electrode in the plan view.

18. The method of claim 17, wherein with respect to the upper surface of the lower electrode, a height of an upper surface of the pixel defining layer in the second area is greater than a height of the upper surface of the pixel defining layer in the first area.

19. The method of claim 17, wherein with respect to the upper surface of the lower electrode, a height of an upper surface of the pixel defining layer in the first area is less than about 1.0 micrometer.
